(19) United States
(12) Patent Application Publication
(10) Pub. No.: US 2024/0215319 A1
(43) Pub. Date: Jun. 27, 2024

(54) DISPLAY PANEL AND DISPLAY DEVICE

(71) Applicant: Shanghai Tianma Micro-electronics Co., Ltd., Shanghai (CN)

(72) Inventor: Anqi KANG, Shanghai (CN)

(21) Appl. No.: 18/113,128

(22) Filed: Feb. 23, 2023

(30) Foreign Application Priority Data
Dec. 27, 2022 (CN) 202211689571.1

(51) Int. Cl. H10K 59/122; H10K 59/80

(52) U.S. Cl. CPC H10K 59/122; H10K 59/878; H10K 59/35

(57) ABSTRACT

A display panel includes an array layer and a display device layer located at one side of the array layer. The display device layer includes a plurality of pixels and at least two isolation structures, and the isolation structures are located in peripheral spaces surrounding the pixels.

### CROSS-REFERENCE TO RELATED APPLICATION

This application claims the priority to Chinese patent application No. 202211689571.1, filed on Dec. 27, 2022, the entirety of which is incorporated herein by reference.

### TECHNICAL FIELD

The present disclosure relates to the technical field of display and, more particularly, to a display panel and a display device.

### BACKGROUND

In panel display technologies, organic light-emitting diode (OLED) display technology is different from traditional liquid crystal display (LCD) technology and has characteristics of self-illumination. OLED uses very thin organic material coatings and glass substrates, which has many advantages such as fast response speed, wide viewing angle, rich colors, low power consumption, high and low temperature resistance, etc. Therefore, the OLED has become a key development technology in current industry.

In an OLED display panel, when a certain pixel is controlled to emit light, lateral leakage current will be generated to cause other pixels to emit light, which is called pixel stealing. Although isolation structures can be provided between pixels to block the leakage current, in a display panel with high pixels per inch, there is less space for the isolation structures between pixels. Conflicts in positions of the isolation structures may result in unexpected connections and exacerbate degree of cathode meshing.

### SUMMARY

In accordance with the disclosure, there is provided a display panel including an array layer and a display device layer located at one side of the array layer. The display device layer includes a plurality of pixels and at least two isolation structures, and the isolation structures are located in peripheral spaces surrounding the pixels.

Also in accordance with the disclosure, there is provided a display device including a display panel. The display panel includes an array layer and a display device layer located at one side of the array layer. The display device layer includes a plurality of pixels and at least two isolation structures, and the isolation structures are located in peripheral spaces surrounding the pixels.

Compared with existing technologies, at least the following beneficial effects are achieved in the display panel and display device provided by the present disclosure. The display panel provided by the present disclosure includes the array layer and the display device layer, where the display device layer is configured to arrange the pixels for emitting light, and the array layer is configured to arrange driving circuits for driving the pixels to emit light. The isolation structures are arranged in the peripheral spaces surrounding the pixels of the display device layer, and there are at least two isolation structures. The two isolation structures are configured to block leakage current of the pixels. Two ends of the two isolation structures are not connected, that is, there is an opening between the two isolation structures. The openings can prevent unexpected connections of the isolation structures, which results in aggravation of degree of cathode meshing. Therefore, at least two isolation structures are arranged in the peripheral spaces surrounding the pixels, which can not only block the leakage current of the pixels, but also avoid the aggravation of the degree of the cathode meshing, so that display effect can be ensured.

Any product implementing the present disclosure does not necessarily need to achieve all the above-mentioned technical effects at the same time.

Other features of the present disclosure and advantages thereof will become clearer from the following detailed description of exemplary embodiments of the present disclosure with reference to the accompanying drawings.

### BRIEF DESCRIPTION OF THE DRAWINGS

The accompanying drawings, which are incorporated in and constitute a part of this specification, illustrate the embodiments of the present disclosure and together with the description serve to explain the principles of the present disclosure.

FIG. 1 is a film layer diagram of a display panel in existing technologies.

FIG. 2 is a film layer diagram of a display panel according to an embodiment of the present disclosure.

FIG. 3 is a top view of a display panel according to an embodiment of the present disclosure.

FIG. 4 is a top view of another display panel according to an embodiment of the present disclosure.

FIG. 5 is a top view of an isolation structure according to an embodiment of the present disclosure.

FIG. 6 is a top view of another isolation structure according to an embodiment of the present disclosure.

FIG. 7 is a top view of another isolation structure according to an embodiment of the present disclosure.

FIG. 8 is a top view of another isolation structure according to an embodiment of the present disclosure.

FIG. 9 is a top view of another isolation structure according to an embodiment of the present disclosure.

FIG. 10 is a top view of another isolation structure according to an embodiment of the present disclosure.

FIG. 11 is a top view of another display panel according to an embodiment of the present disclosure.

FIG. 12 is a top view of another display panel according to an embodiment of the present disclosure.

FIG. 13 is a top view of another display panel according to an embodiment of the present disclosure.

FIG. 14 is a top view of another display panel according to an embodiment of the present disclosure.

FIG. 15 is a film layer structure diagram of another display panel according to an embodiment of the present disclosure.

FIG. 16 is a partial enlarged view of FIG. 15.

FIG. 17 is another partial enlarged view of FIG. 15.

FIG. 18 is a film layer structure diagram of another display panel according to an embodiment of the present disclosure.

FIG. 19 is a partial enlarged view of FIG. 18.

FIG. 20 is a film layer structure diagram of another display panel according to an embodiment of the present disclosure.

FIG. 21 is a film layer structure diagram of another display panel according to an embodiment of the present disclosure.

FIG. 22 is a schematic structural view of a barrier wall according to an embodiment of the present disclosure.

FIG. 23 is a top view of a display device according to an embodiment of the present disclosure.

### DETAILED DESCRIPTION OF THE EMBODIMENTS

Various exemplary embodiments of the present disclosure will be described in detail with reference to the accompanying drawings. It should be noted that relative arrangements of components and processes, numerical expressions, and numerical values set forth in the embodiments do not limit the scope of the present disclosure unless specifically stated otherwise.

The following description of at least one exemplary embodiment is only illustrative in nature and in no way taken as any limitation of the present disclosure, and application or use thereof.

Techniques, methods, and devices known to those of ordinary skill in the art may not be discussed in detail, but where appropriate, such techniques, methods, and devices should be considered a part of this specification.

In all examples shown and discussed herein, any specific values should be construed as exemplary only, and not as limitations. Therefore, other instances of the exemplary embodiments may have different values.

It should be noted that similar numbers and letters refer to similar items in the following figures. Therefore, once an item is defined in one figure, it does not require further discussion in subsequent figures.

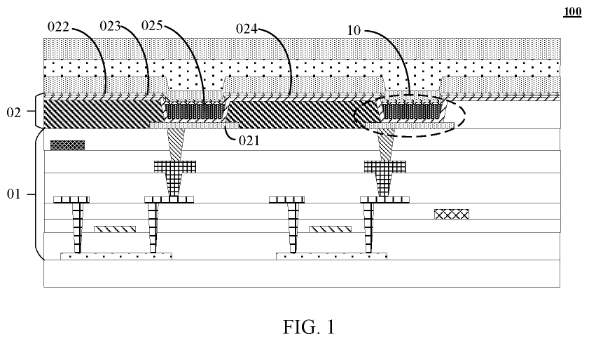

Referring to FIG. 1, it is found through research that a working principle of an OLED display panel is to apply voltage to an anode 021 and a cathode 022. Under an action of an electric field formed by the anode 021 and the cathode 022, holes are transported to an organic light emission layer 025 through a first common layer 023, and electrons are transferred to the organic light emission layer 025 through a second common layer 024. The holes and the electrons are recombined in the organic light emission layer 025 to emit light. However, since adjacent pixels 10 can be connected through the first common layer 023, when one pixel 10 emits light, a small amount of holes can be injected into adjacent pixels 10 through the first common layer 023, and recombines with the electrons in adjacent pixel 10 to emit light. Current formed by leakage of a small amount of holes is called leakage current, and an unexpected light emission phenomenon of the pixel 10 due to the leakage current is called pixel stealing.

In related technologies, single isolation structures are provided between pixels to block the leakage current. However, reliability of the single isolation structure is low.

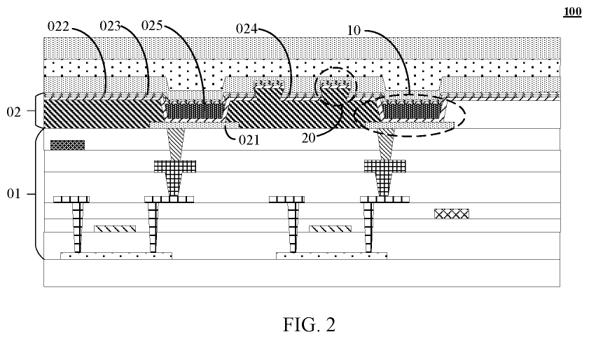

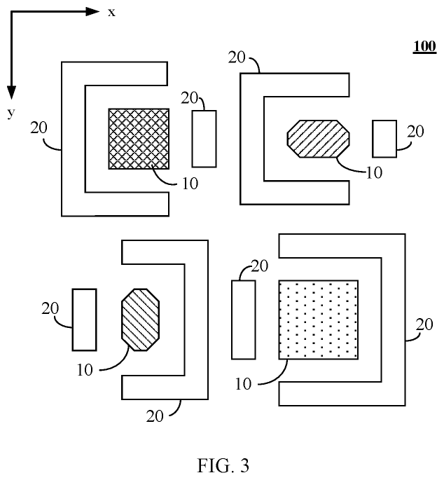

In order to solve the above technical problems, the present disclosure provides a display panel, as shown in FIGS. 2 and 3. FIG. 2 is a film layer diagram of a display panel according to an embodiment of the present disclosure, and FIG. 3 is a top view of a display panel according to an embodiment of the present disclosure. The present disclosure provides a display panel 100, which includes an array layer 01 and a display device layer 02 located at one side of the array layer 01. The display device layer 02 includes a plurality of pixels 10 and at least two isolation structures 20, and the isolation structures 20 are located in peripheral spaces surrounding the pixels 10.

It can be understood that the display device layer 02 is located at one side of the array layer 01 close to a light emission surface of the display panel 100. The display device layer 02 is configured to arrange the pixels 10 for light emission, and the array layer 01 is configured to arrange driving circuits for driving the pixels 10 to emit light.

In some embodiments, the display device layer 02 includes the anode 021, the first common layer 023, the cathode 022, the second common layer 024, and the organic light emission layer 025. Voltage is applied to the anode 021 and the cathode 022. Under the action of the electric field formed by the anode 021 and the cathode 022, the holes are transported to the organic light emission layer 025 through the first common layer 023, and the electrons are transferred to the organic light emission layer 025 through the second common layer 024. The holes and the electrons are recombined in the organic light emission layer 025 to emit light.

Further, the plurality of the pixels 10 are arranged in an array at the display device layer 02, and the isolation structures 20 are provided in the peripheral spaces surrounding the pixels 10.

It can be understood that the isolation structures 20 are also arranged at the display device layer 02 and have certain heights or depths. Therefore, when the first common layer 023, the second common layer 024, and the cathode 022 are being fabricated, faults thereof will be formed at sides of the isolation structures 20 along thickness direction of the display panel 100. In this way, even if a small amount of the holes flow out through the first common layer 023 when a pixel 10 emits light, the holes cannot be continue to be injected into adjacent pixels 10 because the first common layer 023 is cut off by the isolation structures 20, so that the pixel stealing of adjacent pixels 10 can be avoided, and an display effect can be improved.

It should be noted that there are multiple pixels 10, and only one pixel unit is taken as an example for illustration in FIG. 3. The pixel unit can be regarded as a smallest repeating unit of the pixels 10 at the display device layer 02. In the pixel unit shown in FIG. 3, at least four pixels 10 are included. In some other embodiments of the present disclosure, number of the pixels 10 included in the pixel unit may also be 3, 5, etc., which is not limited herein. Also, only that outlines of the pixels 10 are squares or octagons is taken as an example for illustration in FIG. 3. In some other embodiments of the present disclosure, the outlines of the pixels 10 can also be embodied in other shapes, such as rectangles, circles, ellipses, etc., which is not limited herein.

It can be understood that the isolation structure 20 includes at least two isolation structures 20, which are both located in the peripheral spaces surrounding the pixels 10. The two isolation structures 20 may be located at opposite sides of the same pixel 10. For example, from a top view, the two isolation structures 20 may be respectively located at upper and lower sides, or left and right sides of the same pixel 10. Meanwhile, the two isolation structures 20 may also be located at two adjacent sides of the same pixel 10. For example, from a top view, the two isolation structures 20 may be respectively located at the upper and the left sides, or the lower and the right sides of the same pixel 10.

It should be noted that the fact that the isolation structures 20 are located at a certain side of the pixels 10 does not mean that all parts of the isolation structures 20 need to be located at the certain side of the pixels 10. Referring to FIG. 2, the isolation structures 20 in a “concave” shape can be considered to be located at the left or the right side of the pixels 10.

Further, no matter whether the two isolation structures 20 are located at opposite sides or adjacent sides of the same pixel 10, it is required that two ends of the two isolation structures 20 are not connected. In other words, there needs to be an opening between the two isolation structures 20.

In some embodiments, along the thickness direction of the display panel 100, the cathode 022 is arranged at an upper layer of the isolation structures 20. Since the cathode 022 is fabricated on an entire surface, when the isolation structures 20 with certain heights or depths are arranged in the periphery spaces surrounding the pixels 10, the cathode 022 will be cut off at the sides of the isolation structures 20 along the thickness direction of the display panel 100. Along the thickness direction of the display panel 100, the cathode 022 located at the upper layer of the isolation structures 20 is not connected to the cathode 022 on the entire surface, which is equivalent to a hollow area of the cathode 022 on the entire surface. Forming the hollow area on the entire surface of the cathode 022 is called cathode meshing, which causes increased loading on the cathode 022 and also causes discontinuity in cathode signals. Therefore, in the embodiments provided by the present disclosure, along the thickness direction of the display panel 100, positions and projected areas of the isolation structures 20 only need to meet requirements of blocking leakage current. An unnecessary increase in an area of the hollow area of the cathode 022 due to connection of the two isolation structures 20 is called an unexpected connection of the isolation structures 20. Therefore, in the embodiments provided by the present disclosure, there is an opening between the two isolation structures 20, so as to avoid the excessive area of the hollow area of the cathode 022 caused by the unexpected connections of the isolation structures 20, which aggravates the cathode meshing.

In an embodiment provided by the present disclosure, pixels per inch (PPI) of the display panel 100 is greater than 500.

It can be understood that the PPI refers to number of pixels per inch. Therefore, a higher PPI value indicates that the display panel 100 can display images with higher density. That is, the higher fineness of the display images, the better the display effect.

While the display panel 100 with high PPI provides high-precision display images, spaces between the pixels 10 are too small, which is easy to generate the leakage current and cause the pixel stealing of the pixels 10. In related technologies, single isolation structures are provided between adjacent pixels 10 to prevent the leakage current. However, the reliability of the single isolation structure is low. Especially in the display panel 100 provided by the present disclosure with the PPI greater than 500, the spaces between adjacent pixels 10 are too small. If the single isolation structures fail to isolate common layers between adjacent pixels 10, it will easily cause the leakage current, resulting in the pixel stealing of adjacent pixels 10.

Therefore, an application scenario of the embodiments of the present disclosure is that in the display panel 100 with the PPI greater than 500, at least two isolation structures 20 are provided in the peripheral spaces surrounding the pixels 10 in the display panel 100, as described above. Compared with existing technologies, at least two isolation structures 20 are included in the peripheral spaces surrounding any pixel 10 in the present disclosure. Therefore, at least two isolation structures 20 are included between adjacent pixels 10. For a pixel 10, the isolation structures 20 surrounding the pixel 10 can prevent the leakage current generated by the pixel 10 from flowing out and affecting adjacent pixels 10. For multiple pixels 10, the isolation structures 20 surrounding each pixel 10 can prevent the leakage current generated by each pixel 10 from flowing in and affecting the pixel 10. In the embodiments of the present disclosure, a relatively high-precision graphic design is performed on the isolation structures 20 in the display panel 100 with high PPI, which ensures the display effect of the display panel 100.

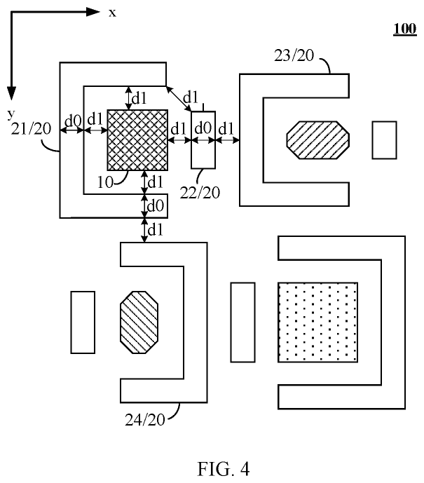

In an embodiment provided by the present disclosure, referring to FIG. 4, which is a top view of another display panel according to an embodiment of the present disclosure, width do of the isolation structure 20 is 3 μm to 5 μm. The width do of the isolation structure 20 refers to length of the isolation structure 20 along a direction connecting two pixels 10 adjacent to the isolation structure 20.

It can be understood that, in the display panel 100 with high PPI, the spaces between adjacent pixels 10 are relatively small. In order to meet the requirement that the isolation structures 20 can be provided between adjacent pixels 10 to block the leakage current of the pixels 10, and meanwhile, to avoid unexpected connections between the isolation structures 20 that results in aggravated cathode meshing, the width do of the isolation structure 20 provided by the embodiments of the present disclosure is 3 μm to 5 μm.

It should be noted that, in the embodiments provided by the present disclosure, the width do of the isolation structure 20 refers to the length of the isolation structure 20 along the direction connecting two adjacent pixels 10.

In some embodiments, referring to FIG. 4, an isolation structure 22 is located between adjacent pixels 10 along a first direction x, and the width do of the isolation structure is length of the isolation structure 22 along the first direction x.

Referring to FIG. 4 again, an isolation structure 21 is partly located between adjacent pixels 10 along the first direction x, and partly located between adjacent pixels 10 along a second direction y. Then, width do of a portion extending along the first direction x and width do of a portion extending along the second direction y of the isolation structure 20 both satisfy to be 3 μm to 5 μm.

It should be noted that the width do of the isolation structure 20 is 3 μm to 5 μm, which is in an embodiment provided by the present disclosure. The width of the isolation structure 20 may also be 4 μm, 2 μm, 6 μm, etc., which is not limited herein. The width do of the isolation structure 20 can be determined according to the PPI of the display panel 100. For example, when the PPI of the display panel 100 is 500, the width do of the isolation structure 20 is 3 μm to 5 μm; when the PPI of the display panel 100 is 700, the width do of the isolation structure 20 is 2 μm to 3 μm; when the PPI of the display panel 100 is 300, the width do of the isolation structure 20 is 5 μm to 7 μm. That is, when the PPI of the display panel 100 is high, the spaces between adjacent pixels 10 are small, and the width do of the isolation structure 20 between adjacent pixels 10 is small; when the PPI of the display panel 100 is low, the spaces between adjacent pixels 10 are large, and the width do of the isolation structure 20 between adjacent pixels 10 is large.

It can be understood that the width do of the isolation structure 20 needs to be set according to actual application scenarios, which is not limited herein. It is found through research that when the width do of the isolation structure 20 is less than 3 μm, manufacturing precision of the isolation structure 20 is high, which increases process cost; when the width do of the isolation structure 20 is greater than 5 μm, projected areas of the isolation structures 20 along the thickness direction of the display panel 100 increase, which results in severe cathode meshing. Therefore, in the embodiments provided by the present disclosure, the width do of the isolation structure 20 is 3 μm to 5 μm. When the width do of the isolation structure 20 is 3 μm to 5 μm, function of blocking the leakage current can be realized, increase of the process cost caused by excessive manufacturing precision can be avoided, and unnecessary hollowing out of the cathode and degree of the cathode meshing can be reduced.

In an embodiment provided by the present disclosure, referring to FIG. 4 again, along a direction parallel to a plane where the display panel is located, a distance between any adjacent isolation structures 20 is first distance d1; or a distance between the isolation structure 20 and the adjacent pixel 10 is first distance d1. The first distance d1 is greater than the width do of the isolation structure 20. The width do of the isolation structure 20 refers to the length of the isolation structure 20 along the direction connecting two adjacent pixels 10.

It should be noted that the direction parallel to the plane where the display panel is located includes at least the first direction x and the second direction y, and the first direction x and the second direction y intersect. The distance between any adjacent isolation structures 20 is the first distance d1, and the first distance d1 has various types. For example, as shown in FIG. 4, the isolation structure 22 and an isolation structure 23 are provided between adjacent pixels 10 along the first direction x, and a distance between the isolation structure 22 and the isolation structure 23 along the first direction x is the first distance d1. Or, the isolation structure 21 and an isolation structure 24 are provided between adjacent pixels 10 along the second direction y, and a distance between the isolation structure 21 and the isolation structure 24 along the second direction y is the first distance d1. When extension directions of adjacent isolation structures 20 are parallel to each other, the first distance d1 refers to a distance between the extension directions of adjacent isolation structures 20. The first distance d1 also includes that if extension directions of the isolation structure 21 and the isolation structure 22 surrounding the same pixel 10 intersect, then a minimum distance between the isolation structure 21 and the isolation structure 22 is the first distance d1.

The distance between the isolation structure 20 and the adjacent pixel 10 is the first distance d1. For example, referring to FIG. 4, the distance between the isolation structure 22 and the pixel 10 is the first distance d1. The isolation structure 21 surrounds the pixel 10. A distance between a portion of the isolation structure 21 extending along the first direction x and the pixel 10 is the first distance d1, and a distance between a portion of the isolation structure 21 extending along the second direction y and the pixel 10 is also the first distance d1.

It should be noted that the first distance d1 is not a fixed distance, but is used to refer to the distance between any adjacent isolation structures 20 or the distance between the isolation structure 20 and the adjacent pixel 10. Further, the first distance d1 refers to a minimum distance between adjacent isolation structures 20 or a minimum distance between the isolation structure 20 and the adjacent pixel 10. Lengths of the multiple first distances d1 may be the same or different.

Further, the first distance d1 is greater than the width do of the isolation structure 20. The width do of the isolation structure 20 refers to the length of the isolation structure 20 along the direction connecting two adjacent pixels 10. In other words, the distance between adjacent isolation structures 20 or the distance between the isolation structure 20 and the adjacent pixel 10 is greater than the width of the isolation structure 20.

It can be understood that the isolation structures 20 are located at one side of the display device layer 02 close to the light emission surface. Along the thickness direction of the display panel 100, the isolation structures 20 have certain heights or depths. Meanwhile, the pixel 10 includes a pixel opening, and the organic light emission layer 025 is filled in the pixel opening. In actual process production, it is difficult to completely fill the organic light emission layer 025 in the pixel opening which causes one side of the organic light emission layer 025 close to the light emission surface to be flush with a pixel definition layer (PDL). Therefore, both the isolation structure 20 and the pixel 10 will cause unevenness at the side of the display device layer 02 close to the light emission surface. However, an encapsulation layer needs to be provided at the side of the display device layer 02 close to the light emission surface. The encapsulation layer is configured to isolate external water and oxygen from invading the display panel 100 and affecting the display effect. Encapsulation materials are naturally leveled at the side of the display device layer 02 close to the light emission surface to form the encapsulation layer. If the first distance d1, which is the distance between adjacent isolation structures 20 or the distance between the isolation structure 20 and the adjacent pixel 10, is smaller than the width do of the isolation structure 20, it will cause small distances between concave parts and convex parts at the side of the display device layer 02 close to the light emission surface, so that it is difficult to fully fill the encapsulation materials in the spaces between adjacent isolation structures 20 or between the isolation structures 20 and the pixels 10. Positions where the encapsulation materials cannot be fully filled may be broken after the encapsulation layer is formed, and then external water and oxygen may invade the display panel 100 through breaks and cause the display device to fail.

It should be noted that the width do of the isolation structure 20 can be set according to actual application scenarios. When the PPI of the display panel 100 is high, the spaces between adjacent pixels 10 are small, and the width do of the isolation structure 20 between adjacent pixels 10 is small; when the PPI of the display panel 100 is low, the spaces between adjacent pixels 10 are large, and the width do of the isolation structure 20 between adjacent pixels 10 is large. In the embodiments provided by the present disclosure, the width do of the isolation structure 20 and the first distance d1 between adjacent isolation structures 20 or between the isolation structure 20 and the adjacent pixel 10 need to be taken into consideration together. For example, along the first direction x, there are two isolation structures 20 between adjacent pixels 10. The width of the isolation structure 20 is do. The distance between the isolation structure 20 and the pixel 10 is d1, and the distance between the isolation structure 20 and the isolation structure 20 is d1. That is, a distance between adjacent pixels 10 is (3×d1+2×d0). When the spaces between adjacent pixels 10 are certain, it is needed to coordinate the width do of the isolation structure 20 and the first distance d1, so that the width do of the isolation structure is appropriate and the first distance d1 is greater than the width of the isolation structure 20.

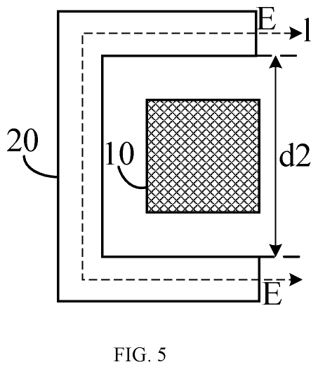

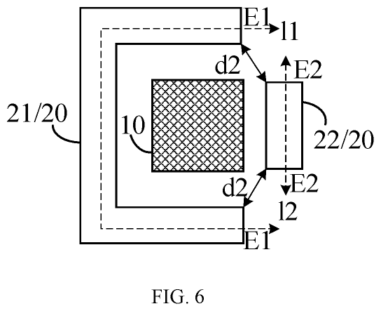

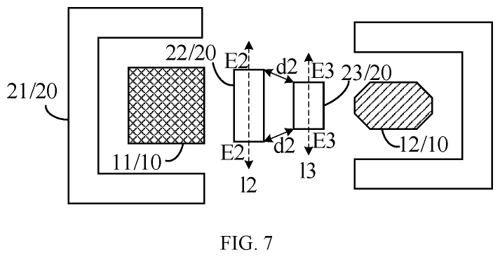

In an embodiment provided by the present disclosure, referring to FIGS. 5 to 7, where FIG. 5 is a top view of an isolation structure according to an embodiment of the present disclosure, FIG. 6 is a top view of another isolation structure according to an embodiment of the present disclosure, and FIG. 7 is a top view of another isolation structure according to an embodiment of the present disclosure, the isolation structure 20 includes two end members E in extension direction 1 of the isolation structure 20. Along the direction parallel to the plane where the display panel 100 is located, distance d2 between any two adjacent end members E is greater than 3 μm.

The any two adjacent end members E of the isolation structure 20 include various embodiments. For example, as shown in FIG. 5, the two adjacent end members E refer to the two end members E of the isolation structure 20 along the extension direction 1. The distance between the two end members E is d2, and d2 needs to be greater than 3 μm, so as to avoid unexpected connections of the isolation structure 20 itself, which results in aggravated cathode meshing. It should be noted that the extension direction of the isolation structure 20 shown in FIG. 5 is a “concave” shape. In some other embodiments of the present disclosure, the extension direction of the isolation structure 20 can also be embodied as a “one” shape, a “seven” shape, etc., which is not limited herein.

In another embodiment, as shown in FIG. 6, the isolation structure 21 and the isolation structure 22 are the isolation structures surrounding the same pixel 10. Extension direction of the isolation structure 21 is 11, and extension direction of the isolation structure 22 is 12. The isolation structure 21 includes two end members E1, and the isolation structure 22 includes two end members E2. In the present embodiment, it is required that distance d2 between the two end members E1 of the isolation structure 21 is greater than 3 μm, and distance d2 between the two end members E2 of the isolation structure 22 is greater than 3 μm. It is also required that distance d2 between the end member E1 of the isolation structure 21 and the end member E2 of the isolation structure 22 is greater than 3 μm. In other words, distances between the end members E of different isolation structures 20 surrounding the same pixel 10 need to be greater than 3 μm. It should be noted that in FIG. 5, the extension direction 11 of the isolation structure 21 is in a “concave” shape, and the extension direction 12 of the isolation structure 22 is in a “one” shape. In some other embodiments of the present disclosure, it can also be embodied that the extension directions of the isolation structure 21 and the isolation structure 22 are both in “concave” shapes, and opening directions of the isolation structure 21 and the isolation structure 22 are opposite to each other.

In another embodiment, as shown in FIG. 7, both the isolation structure 22 and the isolation structure 23 are located between pixel 11 and pixel 12. Also, the isolation structure 22 surrounds the pixel 11, and the isolation structure 23 surrounds the pixel 10. The extension direction of the isolation structure 22 is 12, and extension direction of the isolation structure 23 is 13. The isolation structure 22 includes two end members E2, and the isolation structure 23 includes two end members E3. In the present embodiment, it is required that the distance d2 between the two end members E2 of the isolation structure 22 is greater than 3 μm, and distance d2 between the two end members E3 of the isolation structure 23 is greater than 3 μm. It is also required that distance d2 between the end member E2 of the isolation structure 22 and the end member E3 of the isolation structure 23 is greater than 3 μm. In other words, distances between the end members E of adjacent isolation structures 20 surrounding different pixels 10 need to be greater than 3 μm.

It can be understood that the isolation structures 20 are located in the peripheral spaces surrounding the pixels 10, and the isolation structured 20 may extend along one direction, or may extend uninterruptedly along different directions. Distance d2 between the two end members E of the isolation structure 20 is an opening distance of the isolation structure 20. Size of an opening of the isolation structure 20, which is the distance d2 between the two end members E of the isolation structure 20, is greater than 3 μm. In this way, it can be ensured that there are enough spaces between adjacent isolation structures 20 and between the isolation structures 20 and the pixels 10 for the encapsulation materials to flow. For example, as shown in FIGS. 5 and 6, the encapsulation materials need to flow in from spaces between the two end members E of the isolation structure 20 or between the end members E1 of the isolation structure 21 and the end members E2 of the isolation structure 22, to fill spaces between the isolation structures 20 and the pixels 10. As shown in FIG. 7, the encapsulation materials need to flow in from spaces between the end members E2 of the isolation structure 22 and the end members E3 of the isolation structure 23, to fill spaces between the isolation structure 22 and the isolation structure 23. Therefore, in the embodiments provided by the present disclosure, the distance d2 between any two adjacent end members E of the isolation structure 20 is greater than 3 μm, so that it can be ensured that there are enough spaces between the end members E of the isolation structure 20 to allow the encapsulation materials to flow and fill the spaces between adjacent isolation structures 20 or between the isolation structures 20 and adjacent pixels 10. It can also be avoided that the encapsulation layer is broken due to insufficient filling of the encapsulation materials, which will cause the external water and oxygen to invade the display panel 100 through the breaks and cause the display device to fail.

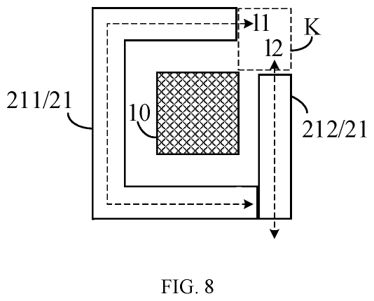

In an embodiment provided by the present disclosure, referring to FIG. 8, which is a top view of another isolation structure according to an embodiment of the present disclosure, the isolation structure 20 includes a first isolation 21, and the first isolation 21 includes at least two sides surrounding the pixel 10 extending in different directions. The first isolation 21 includes at least one opening K, and the opening K passes through the first isolation 21 along the direction parallel to the plane where the display panel 100 is located.

It can be understood that the isolation structures 20 are located in the peripheral spaces surrounding the pixels 10, and the isolation structure 20 includes at least the first isolation 21. The first isolation 21 refers to the isolation structure 20 arranged surrounding the same pixel 10.

Further, the first isolation 21 includes at least two sides surrounding the pixel 10 extending in different directions. Referring to FIG. 8, an extension direction of a first side 211 of the first isolation 21 is a first extension direction 11, and an extension direction of a second side 212 of the first isolation 21 is a second extension direction 12. It should be noted that the first extension direction 11 and the second extension direction 12 are different directions parallel to the plane where the display panel 100 is located.

Further, the first isolation 21 includes at least one opening K, and the opening K passes through the first isolation 21 along the direction parallel to the plane where the display panel 100 is located. It can be understood that the opening K passes through the first isolation 21, that is, at least one opening K separates two sides of the first isolation 21. In this way, the pixel 10 surrounded by the first isolation 21 can be prevented from forming a closed pattern. For example, as shown in FIG. 8, an opening K is included between adjacent end members of the first side 211 and the second side 212 of the first isolation 21, and the opening K prevents the first isolation 21 from forming a closed pattern. On one hand, the opening K can reduce a projected area of the first isolation 21 along the thickness direction of the display panel 100, which avoids unnecessary increase in the degree of the cathode meshing and the area of the hollow area of the cathode caused by the unexpected connections of the first isolations 21. On the other hand, the opening K prevents the first isolation 21 from forming a closed pattern, so that a space of the first isolations 21 pointing to a direction of the pixel 10 is connected with a space of the first isolations 21 away from the direction of the pixel 10, which is beneficial to leveling of the encapsulation materials. Therefore, uneven spaces in the display device layer 02 close to the light emission surface caused by the isolation structures 20 and the pixels 10 can be fully filled to ensure an encapsulation effect.

It should be noted that, in FIG. 8, only an example in which the first isolation 21 includes two sides surrounding the pixel 10 extending in different directions, and the first isolation 21 includes an opening K is used for illustration. In some other embodiments of the present disclosure, the first isolation 21 may also include three sides, four sides, etc. extending surrounding the pixel 10 in different directions. Number of the openings K included in the first isolation 21 may also be two, three, four, etc., which is not limited herein, as long as the openings K of the first isolation 21 all pass through the first isolation 21, and the first isolation 21 cannot form a closed pattern surrounding the pixel 10.

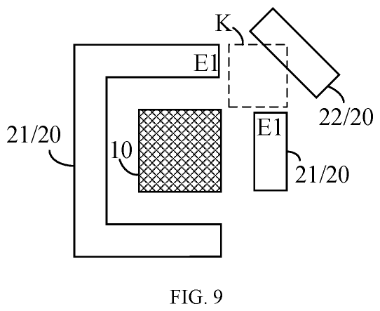

In an embodiment provided by the present disclosure, referring to FIG. 9, which is a top view of another isolation structure according to an embodiment of the present disclosure, the first isolation 21 includes at least two end members E1, and the isolation structure 20 includes at least one second isolation 22. Along at least one direction parallel to the plane where the display panel 100 is located, the second isolation 22 covers at least two adjacent end members E1 surrounding the same pixel 10.

It can be understood that, in some embodiments of the present disclosure, the isolation structure 20 includes a first isolation 21 and at least one second isolation 22. The first isolation 21 is the isolation structure 20 surrounding the pixel, and the second isolation 22 is the isolation structure 20 located between adjacent pixels 10.

Further, the first isolation 21 includes at least two end members E1, and the opening K passing through the first isolation 21 is between two adjacent end members E1. Along a direction from the pixel 10 to the opening K, since there is no barrier of the isolation structure 20, there may be leakage current. The leakage current flows out along the direction from the pixel 10 to the opening K, which causes the pixel stealing of adjacent pixels 10 and affects the display effect. Therefore, along at least one direction parallel to the plane where the display panel 100 is located, the second isolation 22 covers at least two adjacent end members E1 surrounding the same pixel 10.

It can be understood that the second isolation 22 is located between adjacent pixels 10. Along a direction from the second isolation 22 to the pixel 10, projections of the end members E1 of the first isolation 21 fall within a range of projection of the second isolation 22. That is, a maximum range of the leakage current is along the opening K of the adjacent end members E1 of the first isolation 21. An extension direction of the second isolation 22 is perpendicular to the direction from the pixel 10 to the opening K, so that the leakage current from the pixel 10 to the opening K can be blocked by the second isolation 22 after flowing out of the opening K to avoid continuing to flow to adjacent pixels 10, which causes the pixel stealing of adjacent pixels 10 and affects the display effect.

It should be noted that, in FIG. 9, only an example in which the isolation structure 20 includes one second isolation 22 is used for illustration. In some other embodiments of the present disclosure, the second isolations 22 may be arranged according to the openings K passing through the first isolation 21. The openings K are located between adjacent end members E1 of the first isolation 21, so there may be leakage current at the openings K. Therefore, when the first isolation 21 includes a plurality of openings K passing through the first isolation 21, along each direction from the pixel 10 to each opening K, one second isolation 22 that can cover adjacent end members E1 corresponding to the opening K can be provided, so as to block the leakage current at the openings K and improve the display effect.

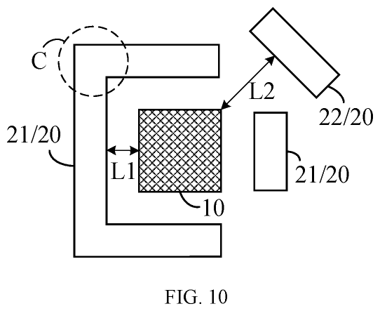

In an embodiment provided by the present disclosure, referring to FIG. 10, which is a top view of another isolation structure according to an embodiment of the present disclosure, the first isolation 21 includes at least one corner C. Along the direction parallel to the plane where the display panel 100 is located, a distance between the first isolation 21 and the pixel 10 is L1, and a distance between the second isolation 22 and the pixel 10 is L2, where L1<L2.

It can be understood that the first isolation 21 is arranged surrounding the pixel 10, and the first isolation 21 includes at least one corner C. When an outline of the pixel 10 is polygonal, an extension direction of the first isolation 21 is along the outline of the pixel 10. When the outline of the pixel 10 is circular or elliptical, the extension direction of the first isolation 21 is a square or a rectangle. Therefore, the first isolation 21 includes at least one corner C.

It can be understood that, along the direction parallel to the plane where the display panel 100 is located, the distance between the first isolation 21 and the pixel 10 is L1, and the distance between the second isolation 22 and the pixel 10 is L2, where L1<L2. In other words, along the direction parallel to the plane where the display panel 100 is located, the first isolation 21 is closer to the pixel 10 than the second isolation 22. When the first isolation 21 is arranged closer to the pixel 10, an area occupied by the first isolation 21, especially the corner C of the first isolation 21 is smaller, which is beneficial to reserve enough space between adjacent pixels 10 for arranging the second isolation 22.

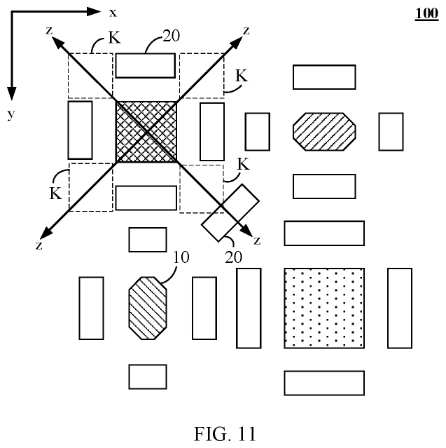

In an embodiment provided by the present disclosure, referring to FIG. 11, which is a top view of another display panel according to an embodiment of the present disclosure, a plurality of pixels 10 are arranged in an array along the first direction x and the second direction y, and the first direction x and the second direction y intersect. Along the direction parallel to the plane where the display panel 100 is located, the opening K is located at one side of the pixel 10 towards a third direction z. The third direction z intersects the first direction x and the second direction y, and is a direction parallel to the plane where the display panel 100 is located.

It can be understood that the display panel 100 includes a plurality of pixels 10, and the plurality of pixels 10 are arranged in an array along the first direction x and the second direction y. Also, along the direction parallel to the plane where the display panel 100 is located, the third direction z intersecting the first direction x and the second direction y is also included.

Further, the opening K passing through the isolation structure 20 is located at one side of the pixel 10 towards the third direction z. In some embodiments, there may be one or multiple openings K. When number of the opening K is one, it may be located at any side of the pixel 10 towards the third direction z. When there are multiple openings K, they may be located at multiple sides of the pixel 10 towards the third direction z.

It can be understood that, since the pixels 10 are arranged in an array along the first direction x and the second direction y, distances between the pixels 10 and the adjacent pixels 10 in the third direction z intersecting the first direction x and the second direction y are larger than distances between the pixels 10 and the adjacent pixels 10 in the first direction x or the second direction y. The opening K is located at one side of the pixel 10 towards the third direction z, which is beneficial to make full use of the large spaces between adjacent pixels 10 along the third direction z to arrange other isolation structures 20.

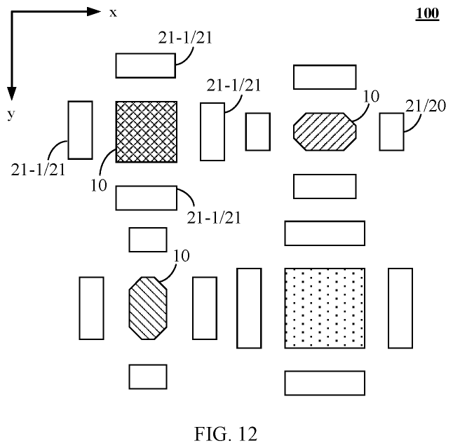

In an embodiment provided by the present disclosure, referring to FIG. 12, which is a top view of another display panel according to an embodiment of the present disclosure, a plurality of pixels 10 are arranged in an array along the first direction x and the second direction y, and the first direction x and the second direction y intersect. The isolation structure 20 includes the first isolation 21, and the first isolation 21 includes a plurality of first subsections 21-1. The first subsections 21-1 are located between adjacent pixels 10 along the first direction x and/or the second direction y, and cover the pixels 10 adjacent to the first subsections 21-1 along the first direction x and/or the second direction y.

It can be understood that the isolation structures 20 are located in the peripheral spaces surrounding the pixels 10. The isolation structure 20 includes the first isolation 21, and the first isolation 21 refers to the isolation structure 20 arranged surrounding the same pixel 10.

Further, the first isolation 21 includes a plurality of first subsections 21-1. Since a plurality of pixels 10 are arranged in an array along the first direction x and the second direction y, the plurality of first sub-sections 21-1 are also located between adjacent pixels 10 along the first direction x and/or the second direction y.

Further, the first subsections 21-1 cover the pixels adjacent to the first subsections 21-1 along the first direction x and/or the second direction y. On one hand, when two pixels 10 are adjacent along the first direction x, the first subsections 21-1 of at least two first isolations 21 respectively surrounding the two pixels 10 are located between the two adjacent pixels 10. Since the two pixels 10 are adjacent along the first direction x, leakage current along the first direction x may be generated between the two pixels 10. Therefore, an extension direction of the first subsection 21-1 located between the two adjacent pixels 10 is the second direction y, and the two first subsection 21-1 respectively cover the adjacent pixels 10. That is, projection of the pixel 10 along the first direction x falls within a range of projection of the first subsection 21-1 adjacent to the pixel 10. In this way, in the first direction x, the first subsection 21-1 can not only block the leakage current generated by the adjacent pixel 10 from flowing out, but also block the leakage current generated by other pixels 10 from flowing to the pixel 10 adjacent to the first subsection 21-1, which avoids interaction among the pixels 10 and improves the display effect.

On the other hand, when two pixels 10 are adjacent along the second direction y, the first subsections 21-1 of at least two first isolations 21 respectively surrounding the two pixels 10 are located between the two adjacent pixels 10. Since the two pixels 10 are adjacent along the second direction y, leakage current along the second direction y may be generated between the two pixels 10. Therefore, an extension direction of the first subsection 21-1 located between the two adjacent pixels 10 is the first direction x, and the two first subsection 21-1 respectively cover the adjacent pixels 10. That is, projection of the pixel 10 along the second direction y falls within a range of projection of the first subsection 21-1 adjacent to the pixel 10. In this way, in the second direction y, the first subsection 21-1 can not only block the leakage current generated by the adjacent pixel 10 from flowing out, but also block the leakage current generated by other pixels 10 from flowing to the pixel 10 adjacent to the first subsection 21-1, which avoids the interaction among the pixels 10 and improves the display effect.

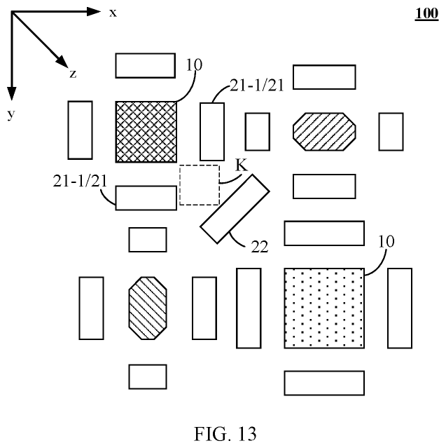

In an embodiment provided by the present disclosure, referring to FIG. 13, which is a top view of another display panel according to an embodiment of the present disclosure, the opening K is included between adjacent first subsections 21-1 surrounding the same pixel 10, and the opening K is located at one side of the pixel 10 towards the third direction z. The isolation structure 20 also includes the second isolation 22. Along the third direction z, the second isolation 22 is located between a connection line of two pixels 10 adjacent to the second isolation 22, and both ends of the second isolation 22 are adjacent to and overlap the opening K. The third direction z intersects the first direction x and the second direction y, and is a direction parallel to the plane where the display panel 100 is located.

It can be understood that the first isolation 21 is the isolation structure 20 surrounding the same pixel 10. The first isolation 21 includes a plurality of first subsections 21-1, and the plurality of first subsections 21-1 extend along the first direction x or the second direction y. The plurality of first subsections 21-1 are not connected, and there is opening K located at one side of the pixel 10 towards the third direction z.

It should be noted that the first direction x, the second direction y, and the third direction z are all parallel to the plane where the display panel 100 is located. The first direction x and the second direction y are perpendicular to each other, and the third direction z intersects both the first direction x and the second direction y. As shown in FIG. 13, an angle between the third direction z and the first direction x is 45°, and an angle between the third direction z and the second direction y is 45°. In some other embodiments of the present disclosure, the angles between the third direction z and the first direction x and the second direction y may also be that the angle between the third direction z and the first direction x is 40°, and the angle between the third direction z and the second direction y is 50°, which is not limited herein. The direction of the third direction z can be determined according to arrangement of the pixels 10.

It can be understood that the opening K between adjacent first subsections 21-1 is located at one side of the pixel 10 towards the third direction z, and the second isolation 22 included in the isolation structure 20 is also located between adjacent pixels 10 along the third direction z. The second isolation 22 extends along a direction perpendicular to the third direction z, and both ends of the second isolation 22 are adjacent to and overlap the opening K along the third direction z. In other words, projection of the second isolation 22 along the third direction z covers projection of the opening K. The opening K is provided between adjacent first subsections 21-1 to avoid the unexpected connections between adjacent first subsections 21-1, which causes unnecessary increase in the area of the hollow area of the cathode and the degree of the cathode meshing. However, arrangement of the opening K may cause the leakage current of the pixel 10 to flow out of the opening K. Therefore, along the third direction z, i.e., the direction from the pixel 10 to the opening K, the second isolation 22 is provided adjacent to the opening K, and the second isolation 22 overlaps the opening K. In this way, the second isolation 22 can block the leakage current of the pixel 10 from the opening K, thereby preventing the leakage current from affecting the adjacent pixels 10 and causing the pixel stealing of the pixels 10, which improves the display effect.

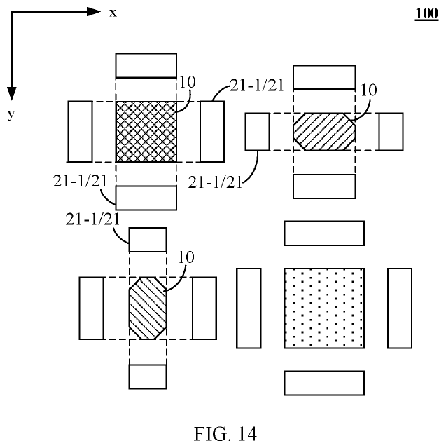

In an embodiment provided by the present disclosure, referring to FIG. 14, which is a top view of another display panel according to an embodiment of the present disclosure, along the first direction x and/or the second direction y, there are at least two first subsections 21-1 between adjacent pixels 10. Along a direction perpendicular to a connection line between the adjacent pixels 10 of the first subsections 21-1, length of the first subsection 21-1 is consistent with length of the adjacent pixel 10.

It can be understood that a plurality of pixels 10 are arranged in an array along the first direction x and the second direction y. Therefore, there are spaces between adjacent pixels 10 along the first direction x and the second direction y. At least two first subsections 21-1 are included between any adjacent pixels 10, and extension directions of the two first subsections 21-1 are the same. For example, when the two first subsections 21-1 are located between two adjacent pixels 10 along the first direction x, the two first subsections 21-1 both extend along the second direction y; when the two first subsections 21-1 are located between two adjacent pixels 10 along the second direction y, the two first subsections 21-1 both extend along the first direction x.

Further, the two subsections 21-1 are respectively opposite to the adjacent pixels 10, and the lengths thereof are consistent with the lengths of the adjacent pixels 10. The length of the first subsection 21-1 refers to the length of the first subsection 21-1 along the extension direction. The length of the pixel 10 refers to the length of the pixel 10 along the extension direction of the adjacent first subsection 21-1.

If the length of the first subsection 21-1 is smaller than the length of the adjacent pixel 10, the projection of the first subsection 21-1 cannot completely cover the projection of the pixel 10 along a direction from the pixel 10 to the first subsection 21-1. In this way, some pixels 10 may generate the leakage current at positions not covered by the first subsections 21-1, which causes the pixel stealing of adjacent pixels 10. If the length of the first subsection 21-1 is greater than the length of the adjacent pixel 10, the projection of the first subsection 21-1 covers and is greater than the projection of the pixel 10 along the direction from the pixel 10 to the first subsection 21-1. In this way, unnecessary increase in the area of the hollow area of the cathode and the degree of the cathode meshing will be caused due to large length of the first subsection 21-1. Therefore, in the embodiments of the present disclosure, the length of the first subsection 21-1 is consistent with the length of the adjacent pixel 10. In this way, in narrow spaces between adjacent pixels 10, the first subsection 21-1 can block the leakage current of the pixels 10, and aggravation of the degree of the cathode meshing can be avoided, which further improves the display effect.

In an embodiment provided by the present disclosure, referring to FIG. 14 again, along the first direction x and/or the second direction y, adjacent pixels 10 emit light in different colors.

It is understood that light is composed of three primary colors, which are red, green, and blue. Combinations of different colors of light can form almost all colors. Therefore, each pixel 10 may only emit light of one color, and light rays from a plurality of pixels 10 emitting light of different colors can be combined to form display images. The present disclosure does not limit light emission color of the pixel 10 to be red, green, or blue. In some other embodiments of the present disclosure, the light emission color of the pixel 10 may also be white, cyan, orange, etc. The display panels 100 with different emission colors have different display effects. For example, when the emission colors of the pixels 10 include red, green, blue, and orange, the display effect of the display panel 100 is warmer; when the emission colors of the pixels 10 include red, green, blue, and cyan, the display effect 100 of the display panel 100 is cooler.

In some embodiments, the adjacent pixels 10 emit light in different colors along the first direction x and/or the second direction y, because emission effects of different colors are different. For example, emission efficiency of blue light is low. Therefore, areas of the pixels 10 that emit blue light will be increased to compensate for chromatic aberration caused by the low emission efficiency of the blue light.

Further, along the first direction x and/or the second direction y, the adjacent pixels 10 emit light in different colors. Therefore, the adjacent pixels 10 have different shapes and sizes. The length of the first subsection 21-1 located between the adjacent pixels 10 is consistent with the length of the adjacent pixel 10. The lengths of two first subsection 21-1 located between the adjacent pixels 10 may be the same or different. The length of the first subsection 21-1 is designed according to the length of the pixel 10 adjacent to the first subsection 21-1, which saves arrangement spaces of the isolation structures 20. While function of the isolation structures to block the leakage current of the pixels 10 is ensured, distances between adjacent first subsections 21-1 are increased, which can effectively avoid unnecessary increase in the degree of the cathode meshing and the area of the hollow area of the cathode caused by unexpected connections between the first subsections 21-1.

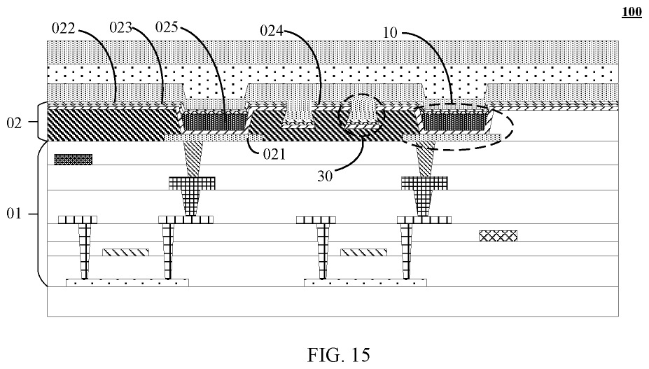

In an embodiment provided by the present disclosure, referring to FIG. 15, which is a film layer structure diagram of another display panel according to an embodiment of the present disclosure, the pixel 10 includes the anode 021. The display panel 100 includes PDL, and the PDL is located at one side of the anode 021 facing the light emission surface of the display panel 100. The isolation structure 20 includes a groove 30 opened in the PDL, and the groove 30 is located between adjacent pixels 10 along a direction perpendicular to the plane where the display panel 100 is located.

It can be understood that the display panel 100 includes the laminated array layer 01 and the display device layer 02. Both the pixels 10 and the isolation structures 20 are located in the display device layer 02.

Further, the display device layer 02 includes the PDL, and the pixel openings are opened at the PDL. The pixel openings are filled with the organic light emission layer 025, and the organic light emission layer 025 is made of organic light emission materials. Meanwhile, the anode 021 of the pixel 10 is provided at one side of the pixel opening close to the array layer 01, and the cathode 022 of the pixel 10 is provided at one side of the pixel opening away from the array layer 01. The first common layer 023 is included between the organic light emission layer 025 and the anode 021, and the second common layer 024 is included between the organic light emission layer 025 and the cathode 022. After the voltage is applied to the anode 021 and the cathode 022, the electric field formed by the anode 021 and the cathode 022 drives both the holes in the first common layer 023 and the electrons in the second common layer 024 to transport to the organic light emission layer 025, which are recombined in the organic light emission layer 025 to emit light.

The pixels 10 are arranged in an array at the display panel 100, and there are spaces between adjacent pixels 10 along a plane where the light emission surface of the display panel 100 is located. The isolation structures 20 are located in the spaces between the adjacent pixels 10. Along the thickness direction of the display panel 100, the isolation structures 20 are the grooves 30 recessed towards the array layer 01. The first common layer 023, the second common layer 024, and the cathode 022 are all fabricated by vapor deposition. Due to existence of the grooves 30, when the first common layer 023, the second common layer 024, and the cathode 022 are being fabricated, fabrication materials will fall into the grooves 30 at positions corresponding to the grooves 30 in the spaces between the pixels 10. However, the fabrication materials cannot be stacked at sides of the grooves 30 along the thickness direction of the display panel 100. Therefore, when the first common layer 023, the second common layer 024, and the cathode 022 are formed, entire surfaces of the first common layer 023, the second common layer 024, and the cathode 022 will be cut off at the sides of the grooves 30 along the thickness direction of the display panel 100. Furthermore, when a pixel 10 emits light, even if there is a small amount of holes flowing out through the first common layer 023, the holes will be blocked at the grooves 30 and cannot continue to flow to the adjacent pixels 10, which avoids the pixel stealing of the adjacent pixels 10 caused by the leakage current.

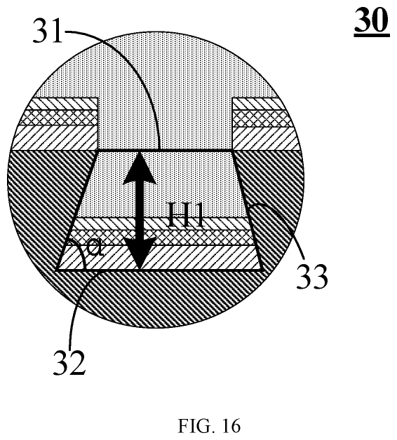

In an embodiment provided by the present disclosure, referring to FIG. 16, which is a partial enlarged view of FIG. 15, a cross section of the groove 30 is a trapezoid along the thickness direction of the display panel 100. Length of a first side 31 of the groove 30 away from the array layer 01 is 3 μm to 5 μm. Height H1 of the groove 30 along the thickness direction of the display panel 100 is 1 μm to 2 μm. Angle α between a second side 32 of the groove 30 close to the array layer 01 and a side 33 connecting the first side 31 and the second side 32 is 45° to 90°.

It can be understood that, since the display panel 100 has high PPI, the spaces between adjacent pixels 10 are narrow. Therefore, in some embodiments, the grooves 30 are patterned to meet requirements that the grooves 30 block the leakage current of the pixels 10.

In some embodiments, the cross section of the groove 30 is a trapezoid along the thickness direction of the display panel 100. The groove 30 includes the first side 31 and the second side 32 that are opposite, where the first side 31 is one side of the groove 30 away from the array layer 01, and the second side 32 is one side of the groove 30 close to the array layer 01. It can be understood that length of the first side 31 is the width of the isolation structure 20 if the display panel 100 of the present disclosure is viewed from top. In some embodiments, the length of the first side 31 is 3 μm to 5 μm. If the length of the first side 31 is less than 3 μm, the width of the isolation structure 20 is too small, so that the manufacturing precision of the isolation structure 20 is high, which increases the process cost. If the length of the first side 31 is greater than 5 μm, the width of the isolation structure 20 is too large, so that the projected area of the isolation structure 20 along the thickness direction of the display panel 100 increases, which results in aggravated cathode meshing.

Further, the height H1 of the groove 30 along the thickness direction of the display panel 100 is 1 μm to 2 μm. It can be understood that isolation function of the groove 30 is due to the fact that the side 33 of the groove 30 along the thickness direction of the display panel 100 has a certain depth. During fabrication process of the first common layer 023, the second common layer 024, and the cathode 022, the first common layer 023, the second common layer 024, and the cathode 022 at positions corresponding to the grooves 30 form drops from the first common layer 023, the second common layer 024, and the cathode 022 at other positions, and the first common layer 023, the second common layer 024, and the cathode 022 cannot be stacked at the sides 33 of the grooves 30. Therefore, isolations are formed between the first common layer 023, the second common layer 024, and the cathode 022 on the entire surface and the first common layer 023, the second common layer 024, and the cathode 022 corresponding to the grooves 30.

The height H1 of the groove 30 determines isolation effect of the isolation structure 20. If the height H1 of the groove 30 along the thickness direction of the display panel 100 is less than 1 μm, the first common layer 023, the second common layer 024, or the cathode 022 evaporated in the groove 30 may protrude from the groove 30. In this way, the groove 30 cannot completely isolate the first common layer 023, the second common layer 024, and the cathode 022, so that the isolation effect of the isolation structure 20 is lost. If the height H1 of the groove 30 along the thickness direction of the display panel 100 is greater than 2 μm, space for forming the groove 30 is too large, and the side of the display device layer 02 close to the light emission surface of the display panel 100 is too uneven, which increases fabrication difficulty of the encapsulation layer.

Further, the angle α between the second side 32 of the groove 30 close to the array layer 01 and the side 33 connecting the first side 31 and the second side 32 is 45° to 90°.

It can be understood that when length of the second side 32 is greater than the length of the first side 31, the angle α between the second side 32 and the side 33 is an acute angle, and the groove 30 is a trapezoid; when the length of the second side 32 is equal to the length of the first side 31, the angle α between the second side 32 and the side 33 is a right angle, and the groove 30 is a rectangle.

First, the length of the second side 32 is not less than the length of the first side 31, so that the groove 30 can be formed into a trapezoid or a rectangle. At this time, the side 33 extends away from center of symmetry relative to the first side 31. In other words, the side 33 is inclined outward from a sectional view. In this way, when the first common layer 023, the second common layer 024, and the cathode 022 are being fabricated, the fabrication materials cannot be stacked at the side 33, so that the first common layer 023, the second common layer 024, or the cathode 022 in the grooves 30 can be isolated from the first common layer 023, the second common layer 024, or the cathode 022 at other positions, which realizes the isolation effect of the isolation structure 20 on the leakage current.

Second, the length of the second side 32 cannot be much greater than the length of the first side 31, which causes the angle α between the second side 32 and the side 33 to be less than 45°. If the angle is too small, space of the groove 30 at the angle is narrow, and the encapsulation materials cannot be fully filled, so that there may be breaks after the encapsulation layer is formed, and then the external water and oxygen may invade the display panel 100 through the breaks and cause the display device to fail. Therefore, in some embodiments, the angle α between the second side 32 and the side 33 connecting the first side 31 and the second side 32 is 45° to 90°.

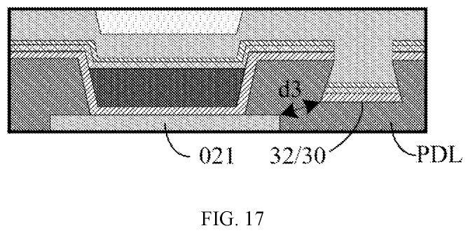

In an embodiment provided by the present disclosure, referring to FIG. 17, which is another partial enlarged view of FIG. 15, distance d3 between the second side 32 of the groove 30 and the anode 021 is greater than or equal to 1 μm along the thickness direction of the display panel 100.

It can be understood that the groove 30 is arranged at the PDL, and the PDL is located at the side of the anode 021 facing the light emission surface of the display panel 100. Therefore, the second side 32 of the groove 30 is close to the anode 021 along the thickness direction of the display panel 100.

Further, the distance d3 between the second side 32 and the anode 021 is greater than or equal to 1 μm. The distance d3 between the second side 32 and the anode 021 refers to a minimum distance between the second side 32 and the anode 021. Referring to FIG. 17, the minimum distance is a distance between adjacent ends of the second side 32 and the anode 021. The distance d3 between the second side 32 and the anode 021 is not less than 1 μm, so that the anode 021 can be prevented from being damaged when the groove 30 is opened.

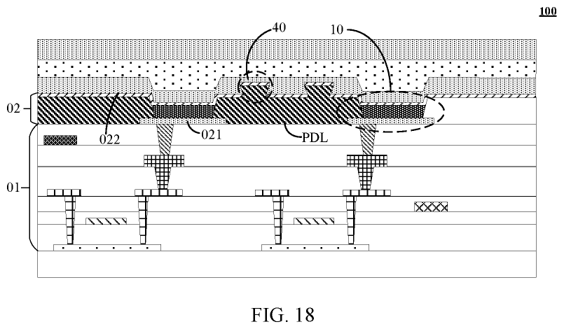

In an embodiment provided by the present disclosure, referring to FIG. 18, which is a film layer structure diagram of another display panel according to an embodiment of the present disclosure, the pixel 10 includes the anode 021. The display panel 100 also includes PDL, and the PDL is located at the side of the anode 021 facing the light emission surface of the display panel 100. The isolation structure 20 includes a barrier wall 40 arranged at the PDL, and the barrier wall 40 is located between adjacent pixels 10 along the direction perpendicular to the plane where the display panel 100 is located.

It can be understood that the display panel 100 includes the laminated array layer 01 and the display device layer 02. Both the pixels 10 and the isolation structures 20 are located in the display device layer 02.

Further, the display device layer 02 includes the PDL, and the pixel openings are opened at the PDL. The pixel openings are filled with the organic light emission layer 025, and the organic light emission layer 025 is made of the organic light emission materials. Meanwhile, the anode 021 of the pixel 10 is provided at the side of the pixel opening close to the array layer 01, and the cathode 022 of the pixel 10 is provided at the side of the pixel opening away from the array layer 01. The first common layer 023 is included between the organic light emission layer 025 and the anode 021, and the second common layer 024 is included between the organic light emission layer 025 and the cathode 022. After the voltage is applied to the anode 021 and the cathode 022, the electric field formed by the anode 021 and the cathode 022 drives both the holes in the first common layer 023 and the electrons in the second common layer 024 to transport to the organic light emission layer 025, which are recombined in the organic light emission layer 025 to emit light.

The pixels 10 are arranged in an array at the display panel 100, and there are spaces between adjacent pixels 10 along the plane where the light emission surface of the display panel 100 is located. The isolation structures 20 are located in the spaces between the adjacent pixels 10. Along the thickness direction of the display panel 100, the isolation structures 20 are the barrier walls 40 protruding towards the array layer 01. The first common layer 023, the second common layer 024, and the cathode 022 are all fabricated by vapor deposition. Due to existence of the barrier walls 40, when the first common layer 023, the second common layer 024, and the cathode 022 are being fabricated, fabrication materials will fall on an upper layer of the barrier walls 40 at positions corresponding to the barrier walls 40 in the spaces between the pixels 10. However, the fabrication materials cannot be stacked at sides of the barrier walls 40 along the thickness direction of the display panel 100. Therefore, when the first common layer 023, the second common layer 024, and the cathode 022 are formed, entire surfaces of the first common layer 023, the second common layer 024, and the cathode 022 will be cut off at the sides of the barrier walls 40 along the thickness direction of the display panel 100. Furthermore, when a pixel 10 emits light, even if there is a small amount of holes flowing out through the first common layer 023, the holes will be blocked at the barrier walls 40 and cannot continue to flow to the adjacent pixels 10, which avoids the pixel stealing of the adjacent pixels 10 caused by the leakage current.

Further, the barrier walls 40 may be formed in the same layer as the PDL and be integrally fabricated. The barrier walls 40 may also be in a different layer from the PDL. After the PDL is fabricated, the barrier walls 40 are formed at one side of the PDL facing the display panel 100.

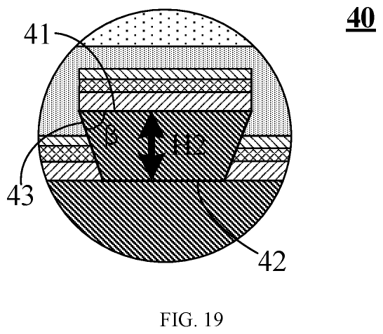

In an embodiment provided by the present disclosure, referring to FIG. 19, which is a partial enlarged view of FIG. 18, a cross section of the barrier wall 40 is an inverted trapezoid along the thickness direction of the display panel 100. Length of a third side 41 of the barrier wall 40 away from the array layer 01 is 3 μm to 5 μm. A side of the barrier wall 40 close to the array layer 01 is a fourth side 42. Angle β between the third side 41 and a side 43 connecting the third side 41 and the fourth side 42 is 45° to 90°.

It can be understood that, since the display panel 100 has high PPI, the spaces between adjacent pixels 10 are narrow. Therefore, in some embodiments, the barrier walls 40 are patterned to meet requirements that the barrier walls 40 block the leakage current of the pixels 10.

In some embodiments, the cross section of the barrier wall 40 is an inverted trapezoid along the thickness direction of the display panel 100. The barrier wall 40 includes the third side 41 and the fourth side 42 that are opposite, where the third side 41 is one side of the barrier wall 40 away from the array layer 01, and the fourth side 42 is one side of the barrier wall 40 close to the array layer 01. It can be understood that length of the third side 41 is the width of the isolation structure 20 if the display panel 100 of the present disclosure is viewed from top. In some embodiments, the length of the third side 41 is 3 μm to 5 μm. If the length of the third side 41 is less than 3 μm, the width of the isolation structure 20 is too small, so that the manufacturing precision of the isolation structure 20 is high, which increases the process cost. If the length of the third side 41 is greater than 5 μm, the width of the isolation structure 20 is too large, so that the projected area of the isolation structure 20 along the thickness direction of the display panel 100 increases, which results in aggravated cathode meshing.

Further, the angle β between the fourth side 42 of the barrier wall 40 close to the array layer 01 and the side 43 connecting the third side 41 and the fourth side 42 is 45° to 90°.

It can be understood that when length of the fourth side 42 is less than the length of the third side 41, the angle β between the third side 41 and the side 33 is an acute angle, and the barrier wall 40 is an inverted trapezoid; when the length of the fourth side 42 is equal to the length of the third side 41, the angle β between the fourth side 42 and the side 33 is a right angle, and the barrier wall 40 is a rectangle.

First, the length of the fourth side 42 is not greater than the length of the third side 41, so that the barrier wall 40 can be formed into an inverted trapezoid or a rectangle. At this time, the side 43 extends away from center of symmetry relative to the third side 41. In other words, the side 43 is inclined inward from a sectional view. In this way, when the first common layer 023, the second common layer 024, and the cathode 022 are being fabricated, the fabrication materials cannot be stacked at the side 43, so that the first common layer 023, the second common layer 024, or the cathode 022 at the upper layer of the barrier wall 40 can be isolated from the first common layer 023, the second common layer 024, or the cathode 022 at other positions, which realizes the isolation effect of the isolation structure 20 on the leakage current.

Second, the length of the fourth side 42 cannot be much less than the length of the third side 41, which causes the angle β between the third side 41 and the side 43 to be less than 45°. If the angle is too small, space at the angle between the barrier wall 40 and the PDL is narrow, and the encapsulation materials cannot be fully filled, so that there may be breaks after the encapsulation layer is formed, and then the external water and oxygen may invade the display panel 100 through the breaks and cause the display device to fail. Therefore, in some embodiments, the angle β between the third side 41 and the side 43 connecting the third side 41 and the fourth side 42 is 45° to 90°.

In an embodiment provided by the present disclosure, referring to FIG. 19 again, height H2 of the barrier wall 40 along the thickness direction of the display panel 100 is 1 μm to 2 μm.

It can be understood that isolation function of the barrier wall 40 is due to the fact that the side 43 of the barrier wall 40 along the thickness direction of the display panel 100 has a certain height. During fabrication process of the first common layer 023, the second common layer 024, and the cathode 022, the first common layer 023, the second common layer 024, and the cathode 022 at positions corresponding to the barrier walls 40 form drops from the first common layer 023, the second common layer 024, and the cathode 022 at other positions, and the first common layer 023, the second common layer 024, and the cathode 022 cannot be stacked at the sides 43 of the barrier walls 40. Therefore, isolations are formed between the first common layer 023, the second common layer 024, and the cathode 022 on the entire surface and the first common layer 023, the second common layer 024, and the cathode 022 corresponding to the barrier walls 40.

The height H2 of the barrier wall 40 determines the isolation effect of the isolation structure 20. If the height H2 of the barrier wall 40 along the thickness direction of the display panel 100 is less than 1 μm, the first common layer 023, the second common layer 024, or the cathode 022 evaporated at other positions may be flush with or protrude from one side of the barrier wall 40 away from the display device layer 02. In this way, the barrier wall 40 cannot completely isolate the first common layer 023, the second common layer 024, and the cathode 022, so that the isolation effect of the isolation structure 20 is lost. If the height H2 of the barrier wall 40 along the thickness direction of the display panel 100 is greater than 2 μm, the barrier wall 40 will conflict with support structures.

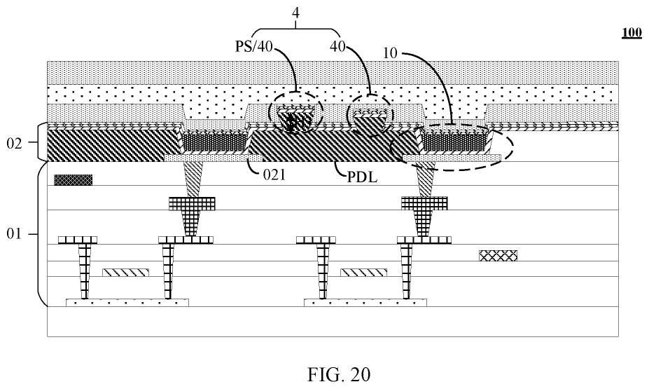

In an embodiment provided by the present disclosure, referring to FIG. 20, which is a film layer structure diagram of another display panel according to an embodiment of the present disclosure, the display panel 100 includes at least one barrier wall group 4, and the barrier wall group 4 includes a plurality of adjacent barrier walls 40. The barrier wall 40 in the barrier wall group 4 is multiplexed as a pillar support (PS), and height H3 of the PS is 1 μm to 3 μm along the thickness direction of the display panel 100.

It can be understood that the barrier wall 40 is located at one side of the PDL close to the light emission surface of the display panel 100, and protrudes towards a direction to the light emission surface of the display panel 100. Therefore, the barrier wall 40 can be multiplexed as the PS.

Further, the height H3 of the barrier wall 40 multiplexed as the PS along the thickness direction of the display panel 100 is 1 μm to 3 μm. In the same display panel 100, the height H3 of the barrier wall 40 is greater than the height H2 of the barrier wall 40 that only serves to block the leakage current.

It can be understood that the PS is configured to support the display panel 100 when the display panel 100 is subjected to an external force, so as to prevent the external force from damaging the display device layer 02 and the array layer 01. The barrier wall 40 is multiplexed as the PS, so that on one hand, no additional support structure is needed, which saves space and process flow of the display panel 100; on the other hand, the height of the barrier wall 40 along the thickness direction of the display panel 100 is increased, and the drops from the first common layer 023, the second common layer 024, and the cathode 022 corresponding to the upper layer of the barrier wall 40 and the first common layer 023, the second common layer 024, and the cathode 022 are increased, which further ensures the isolation effect of the barrier wall.

In an embodiment provided by the present disclosure, number of the barrier walls 40 multiplexed as the PS satisfies:

$$\frac{{A}_{w a l l}}{{A}_{p i x e l}} \times \frac{n}{m} = ( 3 \% - 10 \% ) \qquad ( 1 )$$

$${A}_{wall} = a 1 b 1 + a 2 b 2 + … + a x b x \qquad ( 2 )$$

$$P = nx \qquad ( 3 )$$

where Aₚᵢₓₑₗ is used to represent an area of any pixel unit along the direction parallel to the plane where the display panel 100 is located; A_{wall} is used to represent a total area of a group of the barrier walls 40 multiplexed as the PS located in the spaces surrounding a pixel unit along the direction parallel to the plane where the display panel 100 is located; a is used to represent length of any one of the barrier walls 40 in the group of the barrier walls 40 multiplexed as the PS located in the spaces surrounding a pixel unit; b is used to represent width of any one of the barrier walls 40 in the group of the barrier walls 40 multiplexed as the PS located in the spaces surrounding a pixel unit; x is used to represent number of the barrier walls 40 in a group of the barrier walls 40 multiplexed as the PS located in the spaces surrounding a pixel unit; m is used to represent number of the pixel units; n is used to represent number of groups of the barrier walls 40 multiplexed as the PS located in the spaces surrounding m pixel units; P is used to represent total number of the barrier walls 40 multiplexed as the PS located in the spaces surrounding m pixel units.

It should be noted that light is composed of three primary colors, which are red, green, and blue. Combinations of different colors of light can form almost all colors. Therefore, each pixel 10 may only emit light of one color, and the light rays from a plurality of pixels 10 emitting light of different colors can be combined to form the display images. For example, the light emission color of the pixel 10 is red, green, or blue in some embodiments of the present disclosure. That is, the pixels 10 include the pixels 10 that can emit red light, the pixels 10 that can emit green light, and the pixels 10 that can emit blue light.

In some embodiments of the present disclosure, a pixel unit includes a pixel 10 that can emit red light, a pixel 10 that can emit green light, and a pixel 10 that can emit blue light. The present disclosure does not limit the light emission color of the pixel 10 to be red, green, or blue. In some other embodiments of the present disclosure, the light emission color of the pixel 10 may also be white, cyan, orange, etc., which is not limited herein. When the light emission color of the pixel 10 also includes white, cyan, orange, or another color, correspondingly, a pixel unit also includes a pixel 10 that can emit white light, a pixel 10 that can emit cyan light, a pixel 10 that can emit orange light, or a pixel 10 that can emit another color of light. For example, when the light emission color of the pixel 10 can be white in addition to red, green, and blue, correspondingly, a pixel unit includes a pixel that can emit red light 10, a pixel 10 that can emit green light, a pixel 10 that can emit blue light, and a pixel 10 that can emit white light.

It can be understood that Aₚᵢₓₑₗ is used to represent the area of one pixel unit along the direction parallel to the plane where the display panel 100 is located. Any pixel unit includes a pixel 10 that can emit red light, a pixel 10 that can emit green light, and a pixel 10 that can emit blue light. Therefore, the area of the pixel unit is definite, i.e., Aₚᵢₓₑₗ is a constant value. A_{wall} is used to represent the total area of the barrier walls 40 multiplexed as the PS located in the spaces surrounding a pixel unit along the direction parallel to the plane where the display panel 100 is located. A_{wall} can be determined by formula (2), in which A_{wall}=a1b1+a2b2+ . . . +axbx, where a is used to represent the length of any one of the barrier walls 40 in the group of the barrier walls 40 multiplexed as the PS located in the spaces surrounding a pixel unit, and b is used to represent the width of any one of the barrier walls 40 in the group of the barrier walls 40 multiplexed as the PS located in the spaces surrounding a pixel unit. Therefore, a1b1 is used to represent an area of a first barrier wall, a2b2 is used to represent an area of a second barrier wall, and axbx is used to represent an area of a xth barrier wall. A sum of the areas of the barrier walls 40 multiplexed as the PS is A_{wall}. For example, if 20 barrier walls 40 are included in the spaces surrounding a pixel unit, the length and width of each barrier wall 40 are respectively a and b, and 4 of the 20 barrier walls 40 are multiplexed as the PS, then A_{wall}=4ab. In formula (1),

$$\frac{{A}_{w a l l}}{{A}_{p i x e l}} \times \frac{n}{m}$$

is within a certain range, i.e., 3%-10%. Therefore, in formula (1), n/m needs to be determined, where m is used to represent the number of the pixel units, and n is used to represent the number of groups of the barrier walls 40 multiplexed as the PS located in the spaces surrounding m pixel units. That is, n/m calculates that n groups of the PS need to be arranged in the spaces surrounding m pixel units.

Along the thickness direction of the display panel 100, when number of the barrier walls 40 multiplexed as the PS within a certain projection range is to be determined, number of the pixel units within the projection range is determined, that is, m is known, and Aₚᵢₓₑₗ is determined. A plurality of barrier walls 40 form a group, and x barrier walls 40 in a group of the barrier walls 40 are multiplexed as the PS, where x can be artificially set according to actual process experience. Therefore, when x is uniquely set, A_{wall} can be determined by formula (2). Furthermore, in formula (1), n, which is number of groups of the barrier walls 40 multiplexed as the PS within the projection range, can be obtained. It can be seen from the above that we can determine that there are x barrier walls 40 in a group of the barrier walls 40 that are multiplexed as the PS according to the actual process experience. Therefore, the total number of the barrier walls 40 multiplexed as the PS located in the spaces surrounding m pixel units, which is the number of the barrier walls 40 multiplexed as the PS within the projected range, can be obtained by formula (3).

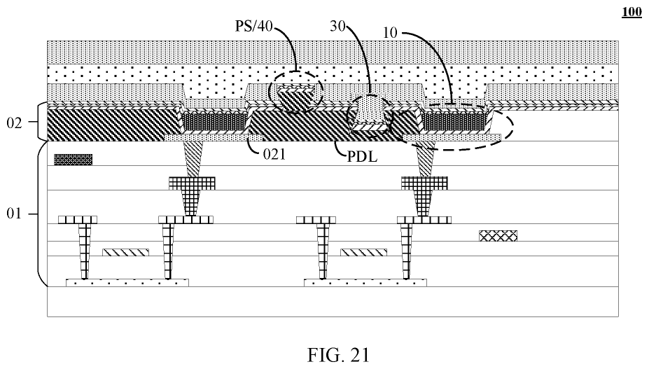

In an embodiment provided by the present disclosure, referring to FIG. 21, which is a film layer structure diagram of another display panel according to an embodiment of the present disclosure, along the direction parallel to the plane where the display panel 100 is located, the isolation structure 20 adjacent to the PS is the groove 30 arranged at the PDL.

It can be understood that at least two isolation structures 20 are included in the peripheral spaces surrounding the pixels 10. When positions adjacent to the isolation structure 20 include the PS, the isolation structure 20 may be the groove 30 arranged at the PDL.

Further, the PS may be the barrier wall 40 multiplexed as the PS, or may be an additional support structure different from the isolation structure 20.

It can be understood that, if the isolation structure 20 adjacent to the PS is the barrier wall 40, there are more protrusions at the side of the PDL close to the light emission surface of the display panel 100, and spaces between the PS and the adjacent barrier wall 40 are narrow. Therefore, the encapsulation materials cannot be fully filled and there may be breaks after the encapsulation layer is formed, and then the external water and oxygen may invade the display panel 100 through the breaks and cause the display device to fail. However, in some embodiments, the isolation structure 20 adjacent to the PS is the groove 30, which can reduce number of the protrusions at the side of the PDL close to the light emission surface of the display panel 100, and can increase spaces between the adjacent PS. Therefore, leveling spaces of the encapsulation materials are increased and a dense encapsulation layer is formed, which is beneficial to improve sealing performance and reliability of the display panel.

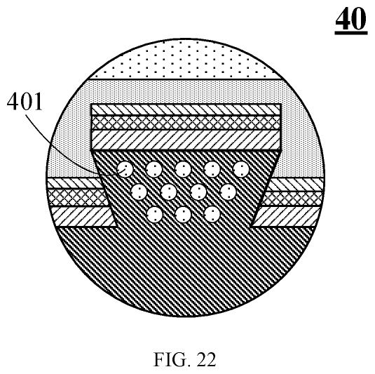

In an embodiment provided by the present disclosure, referring to FIG. 22, which is a schematic structural view of a barrier wall according to an embodiment of the present disclosure, the barrier wall 40 includes reflective particles 401, and the reflective particles 401 are evenly doped in the barrier wall 40.

It can be understood that the barrier wall 40 is located at the side of the PDL close to the light emission surface of the display panel 100, and the light emitted by the pixels 10 is directed in all directions. So, if the light emitted by the pixels 10 is directed towards the barrier wall 40, it will be blocked when encountering the barrier wall 40 and cannot be emitted along the light emission surface of the display panel 100. Therefore, in some embodiments, the reflective particles 401 are evenly doped in the barrier wall 40. Compared with materials of the barrier wall 40, materials of the reflective particles 401 have a higher reflectivity, so that reflection effect of the barrier wall 40 doped with the reflective particles 401 is enhanced. When the pixels 10 emit light directed towards the barrier wall 40, the barrier wall 40 can increase reflectivity of the light, and the reflected light can be emitted along the light emission surface of the display panel 100 again, which improves light output rate of the display panel 100.

For example, the display panel 100 provided in some embodiments may be a display panel using OLED display technology, i.e., an OLED display panel. A basic structure of the OLED display panel generally includes a hole transport layer, a light emission layer, and an electron transport layer. When a power supplies a proper voltage, holes in the anode and electrons in the cathode will combine in the light emission layer to generate bright light. Compared with a liquid crystal display panel, the OLED display panel has characteristics of high visibility and high brightness, and is more power-saving, lighter in weight, and thinner in thickness.

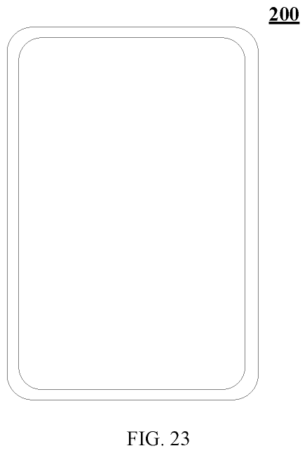

Based on the same inventive concept, the present disclosure also provides a display device, as shown in FIG. 23, which is a top view of a display device according to an embodiment of the present disclosure. The display device 200 includes the display panel 100 in any of the above-mentioned embodiments.

The display device 200 provided by the embodiments of the present disclosure may be any electronic device with a display function, such as a touch screen, a mobile phone, a tablet computer, a notebook computer, an electronic book, a television, etc. The display device 200 provided by the embodiments of the present disclosure has the beneficial effects of the display panel 100 provided by the embodiments of the present disclosure. As for details, reference may be made to the specific descriptions of the display panel 100 in the above embodiments, which will not be repeated herein.

It can be understood only an example in which a shape of the display device 200 is a rectangular structure is used for illustration in FIG. 23. In some other embodiments of the present disclosure, the display device 200 can also be embodied as a rounded rectangle, a circle, an ellipse, or any other feasible shape, which is not limited herein.

As disclosed, at least the following beneficial effects are achieved in the display panel and display device provided by the present disclosure. The display panel provided by the present disclosure includes an array layer and a display device layer, where the display device layer is configured to arrange pixels for emitting light, and the array layer is configured to arrange driving circuits for driving the pixels to emit light. Isolation structures are arranged in the peripheral spaces surrounding the pixels of the display device layer, and there are at least two isolation structures. The two isolation structures are configured to block the leakage current of the pixels. Two ends of the two isolation structures are not connected, that is, there is an opening between the two isolation structures. The openings can prevent the unexpected connections of the isolation structures, which results in the aggravation of the degree of the cathode meshing. Therefore, at least two isolation structures are arranged in the peripheral spaces surrounding the pixels, which can not only block the leakage current of the pixels, but also avoid the aggravation of the degree of the cathode meshing, so that the display effect can be ensured.

Although some embodiments of the present disclosure have been described in detail through examples, those skilled in the art should understand that the above examples are for illustration only and not intended to limit the scope of the present disclosure. Those skilled in the art should understand that modifications can be made to the above embodiments without departing from the scope and spirit of the present disclosure. The scope of the present disclosure is defined by the appended claims.

What is claimed is:

1. A display panel comprising:
an array layer; and
a display device layer located at one side of the array layer;
wherein:
the display device layer includes a plurality of pixels and at least two isolation structures, the isolation structures being located in peripheral spaces surrounding the pixels.

2. The display panel of claim 1, wherein pixels per inch of the display panel is greater than 500.

3. The display panel of claim 1, wherein width of the isolation structure is 3 μm to 5 μm, the width of the isolation structure referring to length of the isolation structure along a direction connecting two pixels adjacent to the isolation structure.

4. The display panel of claim 1, wherein:
a distance between any adjacent isolation structures along a direction parallel to a plane where the display panel is located or a distance between the isolation structure and the adjacent pixel is a first distance; and
the first distance is greater than the width of the isolation structure, the width of the isolation structure referring to length of the isolation structure along a direction connecting two pixels adjacent to the isolation structure.

5. The display panel of claim 1, wherein the isolation structure includes two end members in an extension direction of the isolation structure, a distance between any two adjacent end members being greater than 3 μm along the direction parallel to the plane where the display panel is located.

6. The display panel of claim 1, wherein:
the isolation structure includes a first isolation, the first isolation including at least two sides surrounding the pixel extending in different directions; and
the first isolation includes at least one opening, the opening passing through the first isolation along a direction parallel to a plane where the display panel is located.

7. The display panel of claim 6, wherein:
the first isolation includes at least two end members;
the isolation structure includes at least one second isolation;
along at least one direction parallel to the plane where the display panel is located, the second isolation covers at least two adjacent end members surrounding the same pixel.

8. The display panel of claim 7, wherein:
the first isolation includes at least one corner; and
along the direction parallel to the plane where the display panel is located, a distance between the first isolation and the pixel is L1, and a distance between the second isolation and the pixel is L2, L1 being smaller than L2.

9. The display panel of claim 7, wherein:
a plurality of the pixels are arranged in an array along a first direction and a second direction, the first direction and the second direction intersecting; and
along the direction parallel to the plane where the display panel is located, the opening is located at one side of the pixel towards a third direction, the third direction intersecting the first direction and the second direction, and being a direction parallel to the plane where the display panel is located.

10. The display panel of claim 1, wherein:
a plurality of the pixels are arranged in an array along a first direction and a second direction, the first direction and the second direction intersecting; and
the isolation structure includes a first isolation, and the first isolation includes a plurality of first subsections, the first subsections being located between adjacent pixels along the first direction and/or the second direction, and covering the pixels adjacent to the first subsections along the first direction and/or the second direction.

11. The display panel of claim 10, wherein:
an opening is included between adjacent first subsections surrounding the same pixel, the opening being located at one side of the pixel towards a third direction;
the isolation structure further includes a second isolation; and
along the third direction, the second isolation is located between a connection line of two pixels adjacent to the second isolation, and both ends of the second isolation are adjacent to and overlap the opening, the third direction intersecting the first direction and the second direction, and being a direction parallel to a plane where the display panel is located.

12. The display panel of claim 10, wherein along the first direction and/or the second direction, there are at least two first subsections between adjacent pixels, length of the first subsection being consistent with length of the adjacent pixel along a direction perpendicular to a connection line between the adjacent pixels of the first subsections.

13. The display panel of claim 1, wherein:
the pixel includes an anode;
the display panel includes a pixel definition layer, the pixel definition layer being located at one side of the anode facing a light emission surface of the display panel; and
the isolation structure includes a groove opened in the pixel definition layer, the groove being located between adjacent pixels along a direction perpendicular to a plane where the display panel is located.

14. The display panel of claim 13, wherein:
a cross section of the groove is a trapezoid along thickness direction of the display panel; and
length of a first side of the groove away from the array layer is 3 μm to 5 μm, height of the groove along the thickness direction of the display panel is 1 μm to 2 μm, and an angle between a second side of the groove close to the array layer and a side connecting the first side and the second side is 45° to 90°.

15. The display panel of claim 14, wherein a distance between the second side of the groove and the anode is greater than or equal to 1 μm along the thickness direction of the display panel.

16. The display panel of claim 1, wherein:
the pixel includes an anode;
the display panel further includes a pixel definition layer, the pixel definition layer being located at one side of the anode facing a light emission surface of the display panel; and
the isolation structure includes a barrier wall arranged at the pixel definition layer, the barrier wall being located between adjacent pixels along a direction perpendicular to a plane where the display panel is located.

17. The display panel of claim 16, wherein:
a cross section of the barrier wall is an inverted trapezoid along thickness direction of the display panel; and
length of a third side of the barrier wall away from the array layer is 3 μm to 5 μm, a side of the barrier wall close to the array layer is a fourth side, and an angle between the third side and a side connecting the third side and the fourth side is 45° to 90°.

18. The display panel of claim 17, wherein height of the barrier wall along the thickness direction of the display panel is 1 μm to 2 μm.

19. The display panel of claim 17, further comprising:
at least one barrier wall group including a plurality of adjacent barrier walls;
wherein:
the barrier wall in the barrier wall group is multiplexed as a pillar support, height of the pillar support being 1 μm to 3 μm along the thickness direction of the display panel.

20. The display panel of claim 19, wherein number of the barrier walls multiplexed as the pillar supports satisfies:
$$\frac{{A}_{w a l l}}{{A}_{p i x e l}} \times \frac{n}{m} = ( 3 \% - 10 \% ) ;$$
$${A}_{wall} = a 1 b 1 + a 2 b 2 + … + axbx ; and$$
$$P = nx ;$$
wherein:
Aₚᵢₓₑₗ is used to represent an area of any pixel unit along a direction parallel to the plane where the display panel is located;
A_{wall} is used to represent a total area of a group of the barrier walls multiplexed as the pillar supports located in spaces surrounding a pixel unit along the direction parallel to the plane where the display panel is located;
a is used to represent length of any one of the barrier walls in the group of the barrier walls multiplexed as the pillar supports located in the spaces surrounding a pixel unit;
b is used to represent width of any one of the barrier walls in the group of the barrier walls multiplexed as the pillar supports located in the spaces surrounding a pixel unit;
x is used to represent number of the barrier walls in a group of the barrier walls multiplexed as the pillar supports located in the spaces surrounding a pixel unit;
m is used to represent number of the pixel units;
n is used to represent number of groups of the barrier walls multiplexed as the pillar supports located in the spaces surrounding m pixel units; and
P is used to represent total number of the barrier walls multiplexed as the pillar supports located in the spaces surrounding m pixel units.

21. The display panel of claim 19, wherein along a direction parallel to the plane where the display panel is located, the isolation structure adjacent to the pillar support is a groove arranged at the pixel definition layer.

22. The display panel of claim 16, wherein the barrier wall includes reflective particles, the reflective particles being evenly doped in the barrier wall.

23. A display device comprising:
a display panel including:
an array layer; and
a display device layer located at one side of the array layer;
wherein the display device layer includes a plurality of pixels and at least two isolation structures, the isolation structures being located in peripheral spaces surrounding the pixels.
